(19) United States
(12) Patent Application Publication
(10) Pub. No.: US 2003/0024477 A1
(43) Pub. Date: Feb. 6, 2003

(54) Substrate processing apparatus

(75) Inventors: Kazuyuki Okuda, Tokyo (JP); Toru Kagaya, Tokyo (JP); Masanori Sakai, Tokyo (JP); Shinya Morita, Tokyo (JP); Akira Morohashi, Tokyo (JP)

Correspondence Address: OLIFF & BERRIDGE, PLC, P.O. BOX 19928, ALEXANDRIA, VA, 22320, US

(73) Assignee: HITACHI KOKUSAI ELECTRIC INC., Tokyo (JP)

(21) Appl. No.: 10/207,098

(22) Filed: Jul. 30, 2002

(30) Foreign Application Priority Data
Aug. 2, 2001 (JP) 2001-234841

(51) Int. Cl. C23C 16/00; C23F 1/00

(52) U.S. Cl. 118/723 IR; 118/715; 118/724; 156/345.33; 156/345.35

(57) ABSTRACT

A substrate processing apparatus can efficiently use a gas supplied into a reaction tube by improving a shape of a gas nozzle. A cylinder reaction tube 12 is vertically disposed, and openings of a furnace opening flange 13 is airtightly sealed with a seal cap 14, and a boat 15 onto which wafers W as substrates are loaded in a multi-storied fashion is inserted into the reaction tube 12. A gas is supplied from a nozzle 21 to a plurality of wafers W in the cylindrical reaction tube 12 to deposit a thin film on the wafers W. The nozzle 21 is provided creepingly along an inner wall 22 of the tube in a tube axial direction of the cylinder reaction tube 12. In addition, the nozzle 21 has a nozzle space therein which has an extent of 45° or more and 180° or less in a circumferential direction within the tube. A plurality of gas nozzle openings 24 of the nozzle 21 are provided such that the nozzle openings 24 correspond to the respective wafers W so that a gas flows on the respective wafers W.

### BACKGROUND OF THE INVENTION

1. Field of the Invention

This invention relates to a substrate processing apparatus for processing a plurality of substrates in a reaction tube that is used in one process of manufacturing processes of a semiconductor device, in particular, relates to a substrate processing apparatus wherein a nozzle structure through which a gas is supplied to a plurality of substrates is improved.

2. Description of the Related Art

A conventional vertical type reduced pressure CVD apparatus is shown in FIG. 7. An outer reaction tube 2 is provided inside of a heater 1, and an inner reaction tube 3 is concentrically provided within the outer reaction tube 2. The outer reaction tube 2 and the inner reaction tube 3 are vertically disposed on a furnace opening flange 4. A lower end of the furnace opening flange 4 is airtightly covered with a seal cap 5, and a boat 6 which is vertically disposed on the seal cap S is inserted into the inner reaction tube 3. In the boat 6, a plurality of wafers W to be subjected to a batch process are loaded being horizontally oriented in a multi-storied fashion in a tube axial direction.

A gas introduction nozzle 7 is in communication with the furnace opening flange 4 at a position below the inner reaction tube 3, and an exhaust tube 9 is connected with the furnace opening flange 4 such that the exhaust tube 9 is in communication with a lower end of a cylindrical space 8 which is formed between the outer reaction tube 2 and the inner reaction tube 3.

The boat 6 is moved down by a boat elevator 10 via a seal cap 5, and wafers W are loaded onto the boat 6, and then, the boat 6 is inserted into the inner reaction tube 3 by the boat elevator 10. After the seal cap completely covers a lower end of the furnace opening flange 4, an interior of the outer reaction tube 2 is exhausted.

While being supplied into a reaction chamber from the gas introduction nozzle 7, a reactive gas is exhausted from the gas exhaust tube. An interior of the inner reaction tube 3 is heated to a prescribed temperature, and then, film formation is performed on a surface of the wafers W. After completing the film formation, an inert gas is introduced from the gas introduction nozzle 7 so that the atmosphere inside of the reaction tubes 2 and 3 is substituted for the inert gas and the interiors of the outer and inner tubes 2 and 3 are returned to a normal pressure. Next, the boat 6 is moved down to draw out the wafers W on which the film formation has been completed.

However, in the above-mentioned prior art, there is a problem that a gas can not be efficiently used because an amount of the gas flowing on the substrate is decreased according as the gas is proceeding from a lower portion of the reaction tube to an upper portion of the reaction tube due to the provision of the nozzle at the lower portion of the reaction tube.

This becomes a particular problem in an ALD (Atomic Layer Deposition) apparatus which utilizes only a surface reaction in contrast to the CVD (Chemical Vapor Deposition) apparatus which utilizes a vapor phase reaction and a surface reaction.

Moreover, in the ALD apparatus, active species excited by plasma sometimes are used, and the species excited by plasma, which have a lifetime (lifespan), may be in no excited state due to a certain lapse of time or collision with obstacles. In this respect, in the construction in which the nozzle is provided at the lower portion of the reaction tube, there is also a problem that gas species which require excitement are not transported to the substrate region while the gas species stay in an excited state so that adsorption or reaction can not be performed.

### SUMMARY OF THE INVENTION

An object of the present invention is to provide a substrate processing apparatus wherewith, by resolving the problems with the prior art noted in the foregoing, efficient use of a gas supplied into a reaction tube is possible.

The present invention is a substrate processing apparatus for processing a plurality of substrates by supplying a gas to the plurality of substrates in a cylindrical reaction tube from a nozzle, wherein the nozzle is provided along a tube wall in a tube axial direction of the cylindrical reaction tube, and the nozzle has a nozzle space therein which has an extent of 45° or more and 180° or less in a tube circumferential direction. Although the cylindrical reaction tube is preferably a cylinder reaction tube, it is essential that the cylindrical reaction tube be approximately cylindrical in form. In addition, although the nozzle is preferably provided along the inner wall of the tube, the nozzle may be provided along the outer wall of the tube.

According to the present invention, since the nozzle is provided in the tube axial direction of the cylindrical reaction tube, a gas is uniformly supplied to any position in the tube axial direction of the reaction tube. In addition, since the nozzle is provided along the tube wall, the nozzle can be provided without upsizing of the reaction tube when compared with the nozzle which is provided apart from the tube wall. Moreover, from the viewpoint of downsizing of the apparatus, it is preferable that the nozzle be provided along the inner wall of the tube. Additionally, the provision of the nozzle on the inner wall of the tube also has a merit that a portion without a nozzle can be allowed to function as an exhaust region. Furthermore, since the nozzle has the nozzle space therein which has the extent of 45° or more and 180° or less in the tube circumferential direction, the possibility that a gas collides against the wall can be held down and the pressure in the nozzle can be kept relatively low when comparing with a narrow tubular nozzle. As a result, an amount of adsorption and reaction of a gas against each substrate can be increased so that the gas can be efficiently used.

In the above-mentioned invention, it is preferable that the plurality of substrates be supported by support plates respectively, and that a plurality of gas nozzle openings of the nozzle be provided such that the gas nozzle openings correspond to the substrates supported by the respective support plates. Since the plurality of substrates are supported by the support plates respectively, a gas which exits the gas nozzle openings of the nozzle can be easily spread through regions divided by the support plates between them when comparing with the case wherein no support plate exists. Accordingly, an amount of the gas flowing on the substrates can be raised so that the gas can be more efficiently used. In addition, when the plurality of gas nozzle openings of the nozzle be provided such that the gas nozzle openings correspond to the substrates supported by the respective support plates, flows parallel to surfaces of the substrates can be made so that raw materials can be actively supplied on the substrates so as to be able to promote the surface adsorption.

In the above-stated invention, it is preferable that the gas supplied to the plurality of substrates in the cylindrical reaction tube via the nozzle include a gas activated by plasma. When the gas (species) which is excited by plasma hits against the wall or the pressure is high, the lifetime thereof becomes short. In this respect, since the present invention has a relatively wide nozzle space inside of the nozzle, the lifetime of the species can be secured.

In the above-noted invention, it is preferable that the processing be a process in which plural kinds of gases are repeatedly flowed one by one in turn, on the plurality of substrates and a thin film is formed on the substrates by a surface reaction. When the substrate processing apparatus is applied to the processing in which plural kinds of gases are repeatedly flowed one by one in turn and a thin film is formed by a surface reaction, the surface reaction can be accelerated because the amount of the gas flowing on the substrate is large.

In the above-noted invention, it is preferable that the nozzle has the nozzle space therein which has an extent of 90° or more and 180° or less in the tube circumferential direction.

In the above-noted invention, it is preferable that the processing is a processing in which an Si3N4 film is formed by using SiH2Cl2 and NH3, and the gas activated by plasma is NH3.

In the above-noted invention, it is preferable that the processing is a processing in which plural kinds of gases, include a gas activated by plasma, are repeatedly flowed one by one in turn, on the plurality of substrates and a thin film is formed on the substrates by a surface reaction.

In the above-noted invention, it is preferable that the plural kinds of gases include SiH2Cl2 and NH3, the gas activated by plasma is NH3, and the formed thin film is an Si3N4 film.

In the above-noted invention, it is preferable that a processing temperature is from 300 to 600° C. when performing the processing.

### BRIEF DESCRIPTION OF THE DRAWINGS

FIG. 1 is a schematic sectional view of a vertical type reduced pressure ALD apparatus according to an embodiment;

FIG. 2 is a view of a reaction tube taken along the arrowed line A-A of FIG. 1;

FIG. 3 is a view of a gas nozzle taken in the direction of arrow B of FIG. 2;

FIG. 4 is a schematic sectional view for specifically illustrating a boat structure of a vertical type reduced pressure ALD apparatus according to an embodiment:

FIG. 5 is a plan view of FIG. 4;

FIG. 6 is a plan view of a ring-shaped plate for illustrating a modification example according to an embodiment: and

FIG. 7 is a schematic sectional view of a vertical type reduced pressure CVD apparatus according to a conventional example.

### DESCRIPTION OF THE PREFERRED EMBODIMENTS

Embodiments of a substrate processing apparatus of the present invention that is used in one process of manufacturing processes of a semiconductor device will be described below using drawings. Here, the case where the substrate processing apparatus is applied to a vertical type reduced pressure ALD apparatus will be explained.

First of all, the difference of ALD and CVD will be explained. ALD is a method for performing film formation utilizing only a surface reaction (without utilizing a vapor phase reaction) wherein, under a certain film formation condition (temperature, time and the like), two (or more) kinds of raw material gases to be used for the film formation are alternately supplied one by one on a substrate and allowed to adsorb in one atomic layer unit.

That is , the chemical reaction utilized in ALD is a surface reaction, and a film formation temperature is from 300 to 600° C. (in the case of DCS+NH₃→SiN), which is a relatively low temperature. In contrast, the chemical reaction utilized in CVD is a surface reaction+a vapor phase reaction, and a film formation temperature is from 600 to 800° C. which is a relatively high temperature. In addition, with respect to gas supply, plural kinds of gases are alternately supplied one by one in ALD (not supplied simultaneously), whereas plural kinds of gases simultaneously supplied in CVD. Moreover, with respect to film thickness control, a film thickness is controlled by the number of cycles (for example, if 1 angstrom/cycle, then, the processing is performed by 20 cycles in the case of forming a film of 20 angstroms) in ALD, whereas a film thickness is controlled by a period of time in CVD, which is different from ALD.

In other words, the ALD film formation is a method for forming a film one atomic layer by one atomic layer using a surface reaction without using a vapor phase reaction, by supplying a process gas one kind by one kind on a substrate.

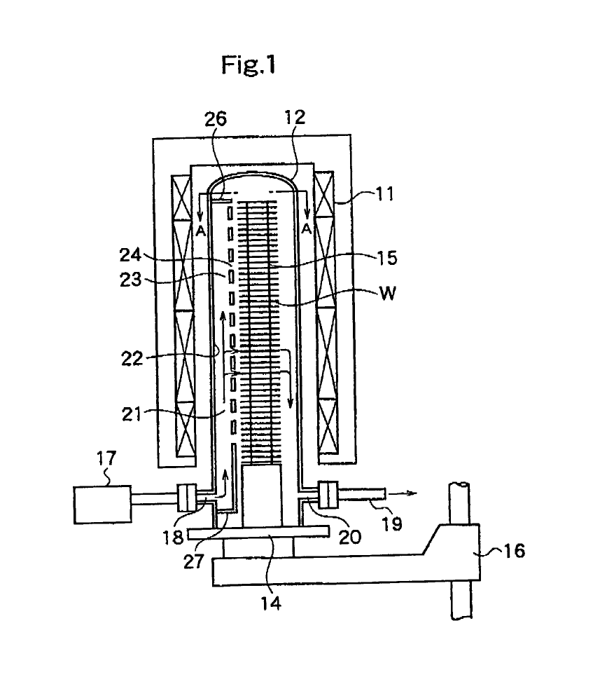

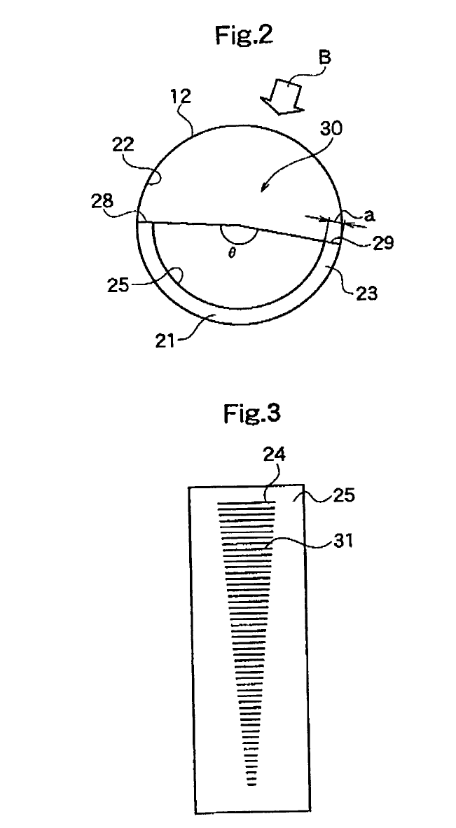

Next, a vertical type reduced pressure ALD apparatus according to the embodiments will be explained using FIGS. 1 to 3. FIG. 1 is a schematic sectional view, FIG. 2 is a view of a reaction tube taken along the arrowed line A-A of FIG. 1, and FIG. 3 is a view of a gas nozzle taken in the direction of arrow B of FIG. 2.

The ALD apparatus shown in FIG. 1 is provided with a cylinder reaction tube 12 made of quartz inside of a heater 11. A lower end of the cylinder reaction tube 12 is airtightly covered with a seal cap 14, and a boat 15 which is vertically disposed on the seal cap 14 is inserted into the cylinder reaction tube 12. In the boat 15, a plurality of wafers W to be processed are loaded being horizontally oriented in a multi-storied fashion. The boat 15 is supported by a boat elevator 16 such that the boat 15 can be allowed to freely move up and down, whereby the boat 15 is adapted to be inserted into or drawn out from the cylinder reaction tube 12.

A gas introduction opening 18 which is connected with a remote plasma unit 17 is provided at one side of a lower portion of the cylinder reaction tube 12, and an exhaust opening 20 which is connected with an exhaust tube 19 in communication with an exhaust pump (not shown) is provided at the other side of the lower portion of the cylinder reaction tube 12. Gases which are supplied to the plurality of wafers W within the cylinder reaction tube 12 through the gas introduction opening 18, include two types of gases: one type of gas activated by plasma and supplied, and the other type of gas supplied without activation by plasma.

The gas introduction opening 18 is in communication with a gas nozzle 21, for example, made of quartz, within the cylinder reaction tube 12, the gas nozzle 21 is provided along an inner wall 22 of the tube in a tube axial direction of the cylinder reaction tube 12, and is creepingly extended along the inner wall 22 of the tube from the lower portion of the reaction tube 12 to a vicinity of a top of the reaction tube 12. The gas nozzle 21 has a relatively wide nozzle space 23 compared to a typical nozzle line having a narrow tube size, and temporarily stores in the nozzle space 23 a gas introduced from the gas introduction opening 18 without directly emitting the gas into the reaction tube 12. The stored gas is adapted to be emitted as indicated by arrows from a plurality of gas nozzle openings 24 provided in the nozzle 21, such that the gas corresponds to a plurality of wafers W.

As shown in FIG. 2, the gas nozzle 21 is of flat shape of arcuate cross section along the inner wall 22 of the cylinder reaction tube 12. The gas nozzle 21 surrounds a part of the inner wall 22 of the cylinder reaction tube 22 so as to be creepingly provided along the inner wall 22 of the reaction tube as described above so that the gas nozzle 21 has the nozzle space 23 of arcuate cross section between the gas nozzle 21 and the inner wall 22. The nozzle space 23 has an extent of the order of θ-45° or more and 180° or less in a tube circumferential direction, preferably an extent of the order of θ=90° or more and 180° or less in a tube circumferential direction, moreover, in the case of setting an inner diameter of the cylinder reaction tube 12 to be the order of 300 mm, the nozzle space 23 has a radial inward width a which is the order of 10 to 40 mm, preferably 15 to 30 mm, which results in a relatively wide space.

The reason why the gas nozzle 21 has a relatively wide nozzle space 23 therein is to prevent the species occurring when a gas is excited by the remote plasma unit 17 from hitting against the wall as far as possible and to keep the pressure in the proximity of plasma occurring region low, which can secure the lifetime of the occurring species so that the species can be transported to the substrate region while the species stay in an excited state.

From the viewpoint of downsizing of the apparatus, it is preferable that the nozzle 21 be provided along the inner wall 22 of the tube. Additionally, the provision of the nozzle 21 on the inner wall 22 of the tube also has a merit that a portion without a nozzle 21 can be allowed to function as an exhaust region.

Furthermore, it is not preferable that the nozzle space 23 have the extent of 45° or less because securing a lifetime of species is difficult so that an amount of adsorption and reaction of a gas cannot be increased effectively. In addition, it is not preferable that the nozzle space 23 have the extent of 180° or more because an exhaust region has to be squeezed or small. On the contrary, it is preferable the nozzle have the extent of 45° or more and 180° or less, because a lifetime of the species can be secured so that an amount of adsorption and reaction of a gas can be increased effectively and an exhaust region does not have to be constrained or small. Moreover, it is more preferable that the nozzle space have the extent of 90° or more and 180° or less, because a lifetime of the species can be further secured so that an amount of adsorption and reaction of a gas can be increased more effectively.

Further, it is not preferable that a radial inward width a of the nozzle be 10 mm or less, because securing a lifetime of species is difficult so that an amount of adsorption and reaction of a gas cannot be increased effectively. In addition, it is not preferable that the width be 40 mm or more because the substrate region has to be squeezed or small. On the contrary, it is preferable that the width be in the range of 10 mm to 40 mm because a lifetime of the species can be secured so that an amount of adsorption and reaction of a gas can be increased effectively and the substrate region does not have to be constrained or small. Moreover, it is more preferable that the width be 15 mm to 30 mm, because a lifetime of the species can be further secured so that an amount of adsorption and reaction of a gas can be increased more effectively.

In order to make the above-stated gas nozzle 21, a nozzle member for surrounding a part of the inner wall 22 of the cylinder reaction tube 12 is constructed from an arc-shaped segment 25 along a tube axial direction. The segment 25 can be, for example, an arc-shaped plate obtained by cutting off a part of cylinder made of quartz in a plane parallel to an axial direction. At every end of the arc-shaped plate, namely at upper, lower, right and left ends of the arc-shaped plate, an upper end blocking plate 26, a lower end blocking plate 27 (see FIG. 1), a right end blocking plate 29 and a left end blocking plate 28 are provided to the inner wall 22 by welding or the like, which respectively fill each of the clearances between the inner wall 22 of the cylinder reaction tube 12 and the segment end portion. The nozzle space 23 is partitioned off from the substrate region 30 on which wafers W are loaded.

As shown in FIG. 3, a plurality of gas nozzle openings 24 are provided on the arc-shaped segment 25 as holes or slits 31 along a tube axial direction, the holes or slits 31 are provided horizontally to correspond to each wafer loaded being horizontally oriented in a multi-storied fashion. In this case, the horizontally provided holes are comprised of a long hole or a plurality of holes arrayed in a line. It is preferable that one or more holes or slits 31 per wafer be provided. This is for making gas flows on the surfaces of wafers, parallel to the surfaces so that the raw material can be actively supplied on the wafers W so as to promote the surface adsorption.

Furthermore, it is preferable a size of the holes or slits 31 be adapted to become larger according as the holes or slits 31 go from a lower portion to an upper portion of the nozzle 21. This is for making the size of the holes or slits 31 at a downstream side of the nozzle 21 larger so that the gas is adapted to easily flow through the holes or slits 31 at the downstream side and that a flow rate can be adjusted between the both sides, because the inner pressure of the nozzle space 23 is reduced lower at the downstream side of the nozzle space 23 than at the upstream side, by a gas ejection from the midway holes or slits 31.

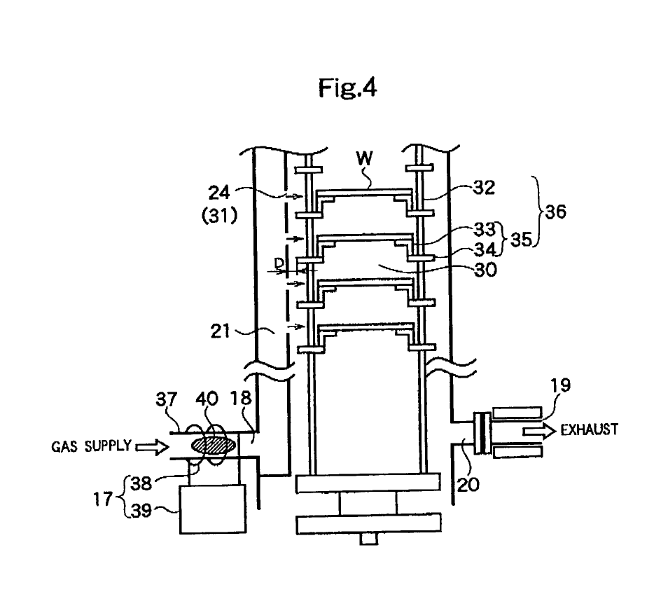

As shown in FIG. 4, a ring boat 36 is used as a boat in which wafers W are loaded. A typical ladder boat (wherein a latch groove is provided on a boat column) used in a vertical type apparatus may be used but the ring boat 36 is more preferable. The ring boat 36 comprises, three or four boat columns 32 disposed vertically which are properly spaced in a circumferential direction and ring-shaped holders 35 as supporting plates provided horizontally being oriented in a multi-storied fashion on the boat columns 32 which support the outer circumference of wafers W from the back surface. The ring-shaped holder 35 comprises a ring-shaped plate 34 which is attached to the boat columns 32 and has a larger outer diameter than that of the wafer W but has a smaller inner diameter than that of the wafer W, and a plurality of wafer holding claws 33 which are disposed on the ring-shaped plate 34 properly spaced in a circumferential direction and hold the back surface of the outer circumference of the wafer W at several points.

When comparing with the case wherein no ring-shaped plate 34 exists, in the case wherein the ring-shaped plate 34 exists, there is an advantage that a gas ejected from the gas nozzle 21 (shown by an arrow) can be easily spread through the substrate regions 30 because a distance D from the holes or the slits 31 of the nozzle 21 to the regions separated for the respective wafers (the regions divided between the ring-shaped plates 34 in this case) becomes short. This leads to keeping a sufficient amount of gas supply onto the wafers W so that decrease in film formation rate and deterioration in uniformity can be prevented.

An induction coil 38 constituting the remote plasma unit 17 is attached to an outer circumference of a discharge tube 37 made of dielectric connected to the outside of the gas introduction opening 18, and the induction coil 38 is connected to an oscillator 39 which generates high frequency electric power. When applying high frequency electric power to the induction coil 38 from the oscillator 39 so as to generate plasma inside of the discharge tube 37 and supplying a gas into the discharge tube in which plasma has been generated, the gas is activated by plasma 40 so that species occur. The species flow into the above-stated nozzle 21.

The gas is supplied through the holes or slits 31 which are provided for respective wafers the gas is supplied between wafers W through the holes or slits 31 and after flowing through the surface of the wafers, it exits the surface and flows into the space opposite to the nozzle 21 and flows downwardly, and then, is exhausted from the exhaust opening 20 of the lower portion of the reaction tube.

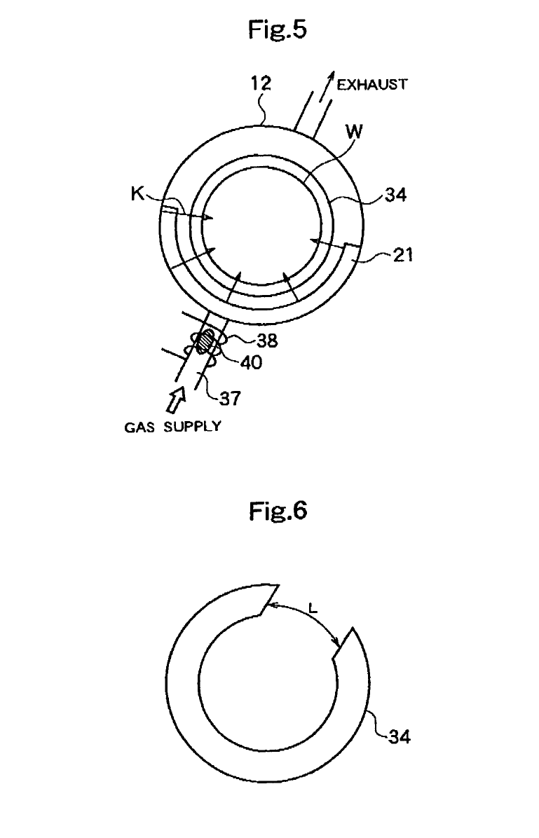

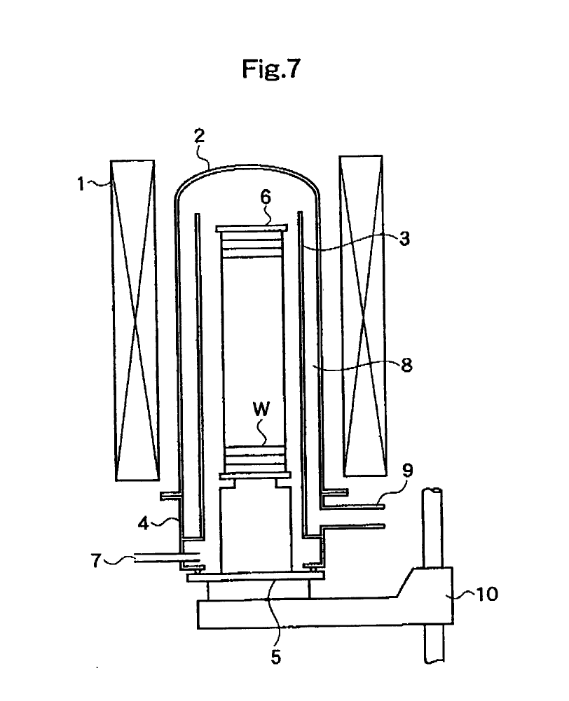

As shown in FIG. 5, a gas K is ejected toward the center of the wafers from an arc-shaped circumferential direction portion of the gas nozzle 21 and is guided between ring-shaped plates 34 to be supplied onto the respective wafers W. In addition, the ring-shaped plate 34 is set to be of closed disk shape. However, as shown in FIG. 6, it may be of C-shape in which a part of a disk is cut out. By cutting out a part of the disk, the cutout portion can be used for transporting wafers. In this case, the wafer holding claws 33 are no longer necessary. As a result, the substrate can be placed directly on the disk so that the supplied gas or species can be utilized more effectively. Moreover, in the case that a boat is not rotated during film formation, the exhaust region can be expanded by directing the cutout portion toward the exhaust region.

Next, the function of the processing apparatus of the embodiment constructed as stated above will be explained. The boat 15 is moved down by the boat elevator 16 via the seal cap 14 and a plurality of wafers W are loaded onto the boat 15, which is inserted into the reaction tube 12 by the boat elevator 16. After the lower end of the cylinder reaction tube 12 is completely sealed with the seal cap 14, an interior of the reaction tube 12 is evacuated to vacuum and exhausted. While a reactive gas is supplied into the reaction chamber from a gas introduction nozzle 21, the gas is exhausted from the gas exhaust opening 20. The interior of the reaction tube 12 is heated to a prescribed temperature, which is kept stable and the film formation processing is performed on the surfaces of wafers W.

To give an example, when performing the film formation processing using two kinds of raw material gases, there is a case that one raw material gas of the two has to be kept at a prescribed temperature or less because vapor phase degradation occurs in the one raw material gas when being supplied whereas the other raw material does not decompose at the temperature or the other raw material does not change into the form which contributes to the reaction. In this case, if the latter material is excited by a remote plasma unit 17 before it is supplied, the film formation sometime can be made. Specifically, for example, in the case that the film formation of nitride film (Si₃N₄ film) is performed by a combination of DCS (dichlorosllane, SiH₂Cl₂) and NH₃, the former is DCS and the latter (excitation by a remote plasma unit is necessary) is NH₃.

However, the species excited by plasma, which have a lifetime (lifespan), may be in no excited state due to a certain lapse of time or collision with obstacles. Unless gas species which require excitement are not transported to the substrate region while the gas species stay in an excited state, adsorption or reaction can not be performed, considering this respect, in this embodiment, a nozzle for an ALD batch process is characterized by its shape which forms a nozzle space 23 which has an arc-shaped extent within the nozzle 21. This makes it possible to supply a gas staying in an excited state to the substrate region and to flow the supplied gas in large amounts efficiently on the surfaces of wafers. In addition to this, since wafers W are supported by the ring-shaped holders 35. a space D between the wafers and the reaction tube becomes small so that a large amount of gas can flow on the surfaces of the wafers and the supplied gas can be used efficiently. As a result, the film formation rate of the thin film can be increased. In addition, in CVD which utilizes a vapor phase reaction, it is intended that a gas is actively consumed by a holder. On the contrary, ALD apparatus which utilizes only a surface reaction is quite different in that it intends to supply a plenty of gases.

The above-stated ALD film formation processing is a process wherein plural kinds of gas are repeatedly flowed one by one in turn, on a plurality of wafers W and a thin film is formed on the plurality of wafers by a surface reaction. The film formation steps will be explained below with the examples using DCS (dichlorosilane:SiH₂Cl₂) and NH₃.

(i) DCS is supplied through the gas nozzle 21 to substrate regions for a prescribed time. At this time, the remote plasma unit 17 is switched off.

(ii) the DCS supply is stopped and N₂ purge or evacuation to vacuum is performed to remove the DCS atmosphere.

(iii) NH₃ is supplied through the gas nozzle 21 to substrate regions for a prescribed time. At this time, the remote plasma unit 17 is switched on and a gas passing through the interior of the discharge tube 37 is excited by plasma.

(iv) the NH₃ supply is stopped and N₂ purge or evacuation to vacuum is performed to remove the NH₃ atmosphere.

Returning to (i) again, steps (i) through (iv) are repeated for desired times. Setting steps (i) through (iv) as one cycle, a film of a certain film thickness is formed during one cycle. Therefore, the film thickness is controlled by the number of cycles.

After completing the film formation in this way, an inert gas is introduced from the gas introduction nozzle 21, so that the atmosphere inside of the cylinder reaction tube 12 is substituted for the inert gas and the interior of the cylinder reaction tube 12 is returned to a normal pressure. Next, the boat 15 is moved down to draw out from the boat 15 the wafers W on which the film formation has been completed.

In addition, although the apparatus wherein the reaction tube has a single tube structure has been explained in the above-stated embodiment, the present invention is not limited to such a structure and it can also be applied to the apparatus wherein the reaction tube has a double tube structure. Further, the present invention is not limited to an ALD apparatus and it can also be applied to a CVD apparatus. Furthermore, although an arc-shaped plate constituting a gas nozzle has been defined as a rectangle with upper and lower sides of the same length, it is not limited to such a construction. For example, the plate can be of an inverted triangular shape wherein the upper portion is wide and the lower portion is narrow.

In addition, although the nozzle has been defined as provided along the inner wall of the tube, it can be provided along an outer wall of the tube.

Moreover, technical ideas which are not mentioned in the claims but still understood by the above-stated respective embodiments and the effects of the ideas will be described below.

(1) A method for processing a substrate, comprising: flowing plural kinds of gases repeatedly one by one in turn, on a plurality of substrates via a gas nozzle, and forming a thin film on the substrates by a surface reaction, wherein the gas nozzle is creepingly formed in a longitudinal direction of a cylinder reaction tube which processes the plurality of substrates, wherein the nozzle is creepingly formed at a part which has an extent of 45° or more and 180° or less, preferably 90° or more and 180° or less in a circumferential direction, and wherein a plurality of gas nozzle openings are provided such that the gas nozzle openings correspond to the respective substrates.

According to this construction, a gas flows uniformly and in large amounts on the surfaces of the respective substrates and a lifetime of species can be secured so that supplied gas can be used efficiently on the respective substrates so as to be able to promote the surface reaction on the respective substrates.

(2) A method for manufacturing a semiconductor device, comprising: flowing plural kinds of gases repeatedly one by one in turn, on a plurality of substrates via a gas nozzle, and forming a thin film on the substrates by a surface reaction, wherein the gas nozzle is creepingly formed in a longitudinal direction of a cylinder reaction tube which processes the plurality of substrates, wherein the nozzle is creepingly formed at a part which has an extent of 45° or more and 180° or less, preferably 90° or more and 180° or less in a circumferential direction, and wherein a plurality of gas nozzle openings are provided such that the gas nozzle openings correspond to the respective substrates.

According to this construction, a gas flows uniformly and in large amounts on the surfaces of the respective substrates and a lifetime of species can be secured so that supplied gas can be used efficiently on the respective substrates so as to be able to promote the surface reaction on the respective substrates. Therefore, a high quality semi-conductor device can be manufactured.

(3) A method for manufacturing a semiconductor device according to the above-noted (2), wherein at least one kind of gas of the plural kinds of gases is activated by plasma to flow.

According to this construction, it is preferable that the gas supplied to the plurality of substrates in the cylinder reaction tube via the nozzle include a gas activated by plasma, when the gas (species) which is activated by plasma hits against the wall or the pressure is high, the lifetime thereof becomes short. In this respect, since the present invention has a relatively wide nozzle space inside of the nozzle, the lifetime of the species can be secured. Therefore, a high quality semiconductor device can be manufactured.

(4) A method for manufacturing a semiconductor device according to the above-stated (3), wherein the plural kinds of gases include DCS and NH₃, wherein the gas which is activated by plasma to flow is NH₃, and wherein the formed thin film is Si₃N₄.

The species excited by plasma, which have a lifetime (lifespan), may be in no excited state due to a certain lapse of time or collision with obstacles. However, according to this construction, gas species which require excitement are transported to the substrate region while staying in an excited state so that adsorption and reaction can be promoted. Therefore, a high quality semiconductor device can be manufactured.

According to the present invention, a gas flows in larger amounts on the surfaces of wafers and a lifetime of species can be secured so that supplied gas can be used efficiently.

What is claimed is:

1. A substrate processing apparatus for processing a plurality of substrates by supplying a gas to said plurality of substrates in a cylindrical reaction tube from a nozzle,
wherein said nozzle is provided along a tube wall in a tube axial direction of said cylindrical reaction tube, and said nozzle has a nozzle space therein which has an extent of 45° or more and 180° or less in a tube circumferential direction.

2. A substrate processing apparatus according to claim 1,
wherein said plurality of substrates are supported by support plates respectively, and
wherein a plurality of gas nozzle openings of said nozzle are provided such that said gas nozzle openings correspond to the substrates supported by said respective support plates.

3. A substrate processing apparatus according to claim 1. wherein the gas supplied to the plurality of substrates in said cylindrical reaction tube via said nozzle includes a gas activated by plasma.

4. A substrate processing apparatus according to claim 1,
wherein said processing is a processing in which plural kinds of gases are repeatedly flowed one by one in turn, on said plurality of substrates and a thin film is formed on said substrates by a surface reaction.

5. A substrate processing apparatus according to claim 1, wherein said nozzle has the nozzle space therein which has an extent of 90° or more and 180° or less in the tube circumferential direction.

6. A substrate processing apparatus according to claim 3, wherein said processing is a processing in which an Si3N4 film is formed by using SIH2Cl2 and NH3, and said gas activated by plasma is NH3.

7. A substrate processing apparatus according to claim 3, wherein said processing is a processing in which plural kinds of gases, include a gas activated by plasma, are repeatedly flowed one by one in turn, on said plurality of substrates and a thin film is formed on said substrates by a surface reaction.

8. A substrate processing apparatus according to claim 7, wherein said plural kinds of gases include SiH2Cl2 and NH3, said gas activated by plasma is NH3, and said formed thin film is an Si3N4 film.

9. A substrate processing apparatus according to claim 8, wherein a processing temperature is from 300 to 600° C. when performing said processing.
